(19) United States
(12) Patent Application Publication
(10) Pub. No.: US 2008/0199995 A1
(43) Pub. Date: Aug. 21, 2008

(54) Integrated Hydrogen Anneal and Gate Oxidation for Improved Gate Oxide Integrity

(76) Inventors: Debra Susan Woolsey, Draper, UT (US); Joelle Sharp, Herriman, UT (US); Tony Lane Olsen, Riverton, UT (US); Gordon K. Madson, Herriman, UT (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/675,596

(22) Filed: Feb. 15, 2007

(51) Int. Cl. H01L 21/336

(52) U.S. Cl. 438/259; 438/270; 257/E21.41; 257/E21.421

(57) ABSTRACT

A method of forming a trench gate field effect transistor includes the following processing steps. Trenches are formed in a semiconductor substrate. The semiconductor substrate is annealed in an ambient including hydrogen gas. A dielectric layer lining at least the sidewalls of the trenches is formed. During the time between annealing and forming the dielectric layer, the semiconductor substrate is maintained in an inert environment to prevent formation of native oxide along sidewalls of the trenches prior to forming the dielectric layer.

### BACKGROUND OF THE INVENTION

The present invention relates in general to semiconductor power field effect transistors (FETs), and more particularly to a method and structure for forming a trench-gate FET and a shielded gate trench FET including integrated hydrogen anneal and gate oxidation.

A cross-sectional view of a conventional trench-gate power MOSFET 10 is shown in FIG. 1. MOSFET 10 includes an n-type substrate 101 on which an n-type epitaxial layer 102 is grown. Substrate 101 embodies the drain of MOSFET 10. A p-type body region 108 extends into epitaxial layer 102. Trenches 113 extend through body region 108 and into the portion of epitaxial layer 102 bounded by body region 108 and substrate 101 (commonly referred to as the drift region). A gate dielectric layer 131 is formed on the sidewalls and bottom of each trench 113. Source regions 110 flank trenches 131. Heavy body regions 137 are formed within body region 108 between adjacent source regions 1 10. Gate electrodes 132 (e.g., from polysilicon) fill trenches 131 and embody the gate of MOSFET 10. Dielectric cap 133 covers trenches 113 and also partially extends over source regions 110. A top-side metal layer 139 electrically contacts source regions 110 and heavy body regions 137. A bottom-side metal layer (not shown) contacts substrate 101.

To increase the transistor packing density, it is desirable to minimize the trench width as well as the mesa width (i.e., the spacing between adjacent trenches). However, both of these dimensions are limited by constraints imposed by manufacturing equipment, structural requirements, misalignment tolerances, and transistor operational requirements. For example, trench MOSFET device performance is closely related to gate oxide quality and reliability. As device dimensions continue to shrink, gate oxide process is becoming increasingly critical.

Thus, there is a need for a technique whereby gate oxide quality and integrity of trench-MOSFETs can be improved while maintaining a simple manufacturing process.

### BRIEF SUMMARY OF THE INVENTION

A method of forming a trench gate field effect transistor includes the following processing steps. Trenches are formed in a semiconductor substrate. The semiconductor substrate is annealed in an ambient including hydrogen gas. A dielectric layer lining at least the sidewalls of the trenches is formed. During the time between annealing and forming the dielectric layer, the semiconductor substrate is maintained in an inert environment to prevent formation of native oxide along sidewalls and bottom of the trenches prior to forming the dielectric layer.

In one embodiment, in forming the dielectric layer an oxidation process is performed to thereby form a gate oxide layer along the sidewalls and bottom of the trenches.

In another embodiment, in forming the dielectric layer a nitridation process is performed to form a silicon nitride layer along the sidewalls of the trenches.

In yet another embodiment, the following steps are carried out after forming the dielectric layer: a gate electrode is formed in each trench; a well region is formed in the semiconductor substrate; source regions are formed in the well region; and heavy body regions are formed in the well region.

In accordance with another embodiment of the invention, a method of forming a shielded gate field effect transistor includes the following processing steps. Trenches are formed in a semiconductor substrate. A shield dielectric layer lining lower sidewalls and bottom of each trench is formed. A shield electrode filling a bottom portion of each trench is formed. The semiconductor substrate is annealed in an ambient including hydrogen gas. A dielectric layer lining at least the upper sidewalls of each trench is formed. During the time between the annealing and forming the dielectric layer, the semiconductor substrate is maintained in an inert environment to prevent formation of native oxide along upper sidewalls of each trench prior to forming the dielectric layer. A gate electrode is formed in an upper portion of each trench.

In one embodiment, in forming the dielectric layer an oxidation process is performed to thereby form a gate oxide layer along the sidewalls and bottom of the trenches.

In another embodiment, a well region is formed in the semiconductor substrate. Source regions are formed in the well region, and heavy body regions are formed conductivity type in the well region.

In accordance with yet another embodiment of the invention, an apparatus for processing a semiconductor substrate includes a first reactor configured to receive the semiconductor substrate and perform hydrogen anneal on the semiconductor substrate, a second reactor configure to receive the semiconductor substrate and form a dielectric layer over the semiconductor substrate, and a transport chamber coupled to the first reactor and the second reactor. The transport chamber is configured to: (a) facilitate transfer of the semiconductor substrate from the first reactor to the second reactor, and (b) have an inert ambient to prevent exposure of the semiconductor substrate to oxygen during transfer of the semiconductor substrate from the first reactor to the second reactor.

In another embodiment, the second reactor is further configured to form the dielectric layer in atmospheric pressure.

In another embodiment, the second reactor is configured to perform an oxidation process.

In accordance with still another embodiment of the invention, an apparatus for performing hydrogen anneal in reduced pressure and forming a dielectric layer in atmospheric pressure includes a reactor for batch processing a plurality of semiconductor wafers, the reactor being capable of maintaining a leak tight condition under a reduced pressure. The apparatus further includes a vacuum system coupled to the reactor for maintaining the reactor in a reduced pressure, and a heating system for maintaining the reactor in a temperature range of about 800° C. to 1200° C. The reactor is configured to receive: (a) hydrogen gas for annealing the plurality of semiconductor wafers, (b) an inert gas for purging the reactor, and (c) an oxygen gas for forming the dielectric layer. In one embodiment, the reactor is further configured to enable forming a layer of silicon nitride.

The following detailed description and the accompanying drawings provide a better understanding of the nature and advantages of the present invention.

### BRIEF DESCRIPTION OF THE DRAWINGS

FIG. 1 shows a cross-section view of a conventional trench-gate MOSFET;

FIGS. 2A-2C are simplified cross-section views illustrating a process flow for forming a trench structure according to an embodiment of the present invention;

FIG. 3A shows a simplified diagram of an apparatus for processing semiconductor wafers according to an embodiment of the present invention;

FIG. 3B shows a simplified diagram of another apparatus for processing semiconductor wafers according to another embodiment of the present invention;

FIGS. 4A-4F are simplified cross-section views illustrating a process flow for manufacturing a trench-gate FET, including integrated hydrogen anneal and oxide formation, according to an embodiment of the present invention; and

FIGS. 5A-5F are simplified cross-section views illustrating a process flow for manufacturing a shielded gate trench-gate FET, including integrated hydrogen anneal and oxide formation, according to another embodiment of the present invention.

### DETAILED DESCRIPTION OF THE INVENTION

In accordance with embodiments of the present invention, a method for forming a trench-gate FET cell structure is provided. In one embodiment, the method includes an integrated hydrogen anneal and gate oxide growth process. Wafer exposure to oxygen is prevented between the anneal process and the gate oxidation process. Depending on the embodiments, hydrogen anneal and gate oxidation can be performed in a single reactor or in separate reactors coupled to a transport chamber. Improved gate oxide quality is achieved in devices such as trench gate FETs or shielded-gate trench FETs.

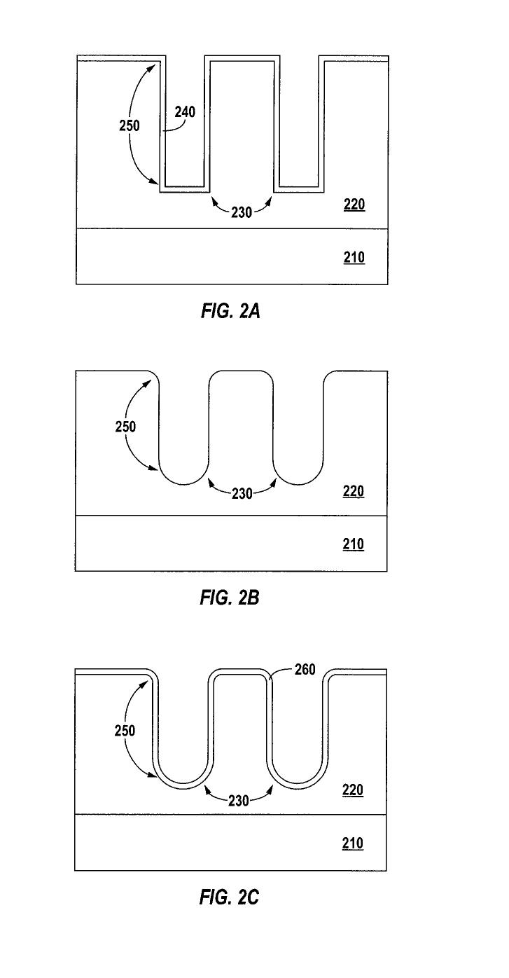

FIGS. 2A-2C are simplified cross-section views illustrating a process flow for manufacturing a trench-gate FET according to an embodiment of the present invention. The following description of the steps in the process flow is only exemplary and it should be understood that the scope of the invention is not limited to this particular example. In particular, processing conditions such as temperature, pressure, layer thicknesses could be possibly varied without departing from the spirit of the invention. As shown in FIG. 2A, the process includes forming an epitaxial layer 220 on a semiconductor substrate 210 using conventional techniques. The process includes forming trenches 230 in the epitaxial layer using conventional techniques. An exemplary process for forming trenches may include forming a masking layer, patterning the masking layer, anisotropically etching the silicon to form trenches, and removing the masking layer.

As shown in FIG. 2A, after the trenches are formed, a layer of native oxide 240 is formed on mesa surfaces and on the sidewalls and bottom of the trenches as a result of exposure to ambient oxygen or moisture, and may include contaminants present in ambient air. The native oxide can degrade gate oxide quality on a silicon surface, in particular where thin gate oxides are to be formed. According to an embodiment of the present invention, a method is provided to remove the native oxide, maintain the silicon in a controlled environment without exposure to oxygen or ambient moisture, and perform a gate oxidation process.

Referring to FIG. 2B, an anneal process is performed using hydrogen gas at a temperature in the range of 700° C. to 1100° C. and a pressure of approximately 100 mTorr to 250 Torr. The use of hydrogen gas reduces the oxygen of the native oxide layer formed on the walls of the trenches. The oxygen reduction process has the effect of removing the native oxide and tying up dangling bonds on the silicon surface defining the walls of the trenches such that the dangling bonds become hydrogen terminated. This condition is desirable, since it allows a higher quality gate oxide to be grown than what would be grown over the native oxide. The anneal step has the effect of not only reducing the oxygen of the native oxide layer, it also causes the upper and lower corners 250 of trenches 230 to become advantageously rounded, as shown in FIG. 2B.

Depending on the embodiment, other temperatures and pressures can be used in the anneal process. For example, in one embodiment, the temperature range is between about 960° C.-1160° C. In another embodiment, the temperature range is between about 800° C.-1000° C. In yet another embodiment, the pressure range can be about 40 Torr to 240 Torr.

FIG. 2B illustrates the trench structure after an anneal process. The anneal process restores the epitaxial layer surface in the trenches to a surface that is substantially defect-free and ready for gate oxide growth via thermal oxidation. It is desirable to prevent native oxide formation before the gate oxidation process. In accordance with the present invention, the semiconductor substrate is maintained in a controlled inert environment between the hydrogen anneal and the oxidation process, thus preventing wafer exposure to oxygen or moisture. In one embodiment, the hydrogen anneal process and the gate oxidation process are performed in a same reactor, or alternatively, in separate reactors which are coupled to a controlled transfer chamber. These and other aspects of the present invention are discussed in detail below.

In FIG. 2C, a gate oxidation process is carried out to form gate oxide layer 260 on exposed silicon surfaces. The oxidation can be carried out using a conventional gate oxidation process. For example, a dry oxidation process, a wet oxidation process, an oxidation process including diluted oxygen or water vapor may be used. In one embodiment, a batch oxidation process under atmospheric pressure is used. In another embodiment, a single wafer oxidation process is used. According to yet another embodiment of the invention, the hydrogen anneal process can be integrated with another dielectric film formation process. Merely as an example, a silicon nitridation process can be integrated following a hydrogen anneal process according to an embodiment of the invention. Of course, many other variations, modifications, and alternatives can be envisioned by one skilled in this art in view of this disclosure.

Many benefits are gained from the integrated hydrogen anneal and dielectric film formation process. For example, the anneal step restores the epitaxial layer surface in the trenches to a surface that is substantially defect-free and ready for gate oxide growth via thermal oxidation. The anneal process also has the effect of rounding the corners of the trenches (FIG. 2C). Further, the rounding etch and HF etch or sacrificial oxide steps used in conventional trench formation processes are eliminated. As a result, narrower trench structures can be obtained, and the entire enhanced trench manufacturing process can be performed with less processing steps. Moreover, the controlled environment keeps the silicon surface from exposure to oxygen, moisture, or ambient contaminants. Gate oxide quality can be improved. The integrated methods in accordance with the invention also simplify manufacturing process flow.

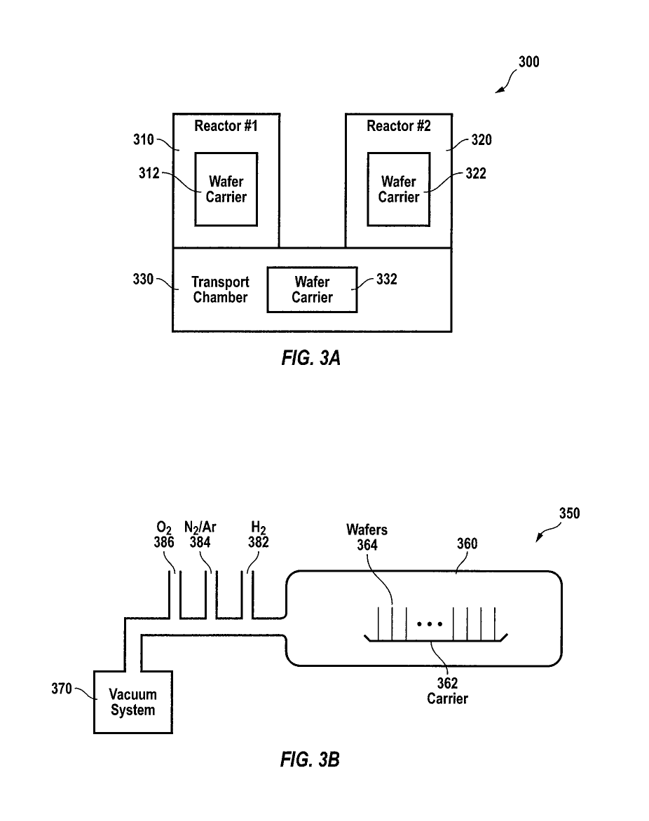

FIG. 3A shows a simplified block diagram of an apparatus 300 for integrated circuit processing according to an embodiment of the present invention. Integrated circuit processing apparatus 300 includes two reactors 310 and 320, and a transport chamber 330. In one embodiment, reactor 310 is configured to perform a hydrogen anneal processes. Examples of hydrogen anneal process according to embodiments of the present invention include the processes described above with reference to FIGS. 2A-2C. In one embodiment, reactor 310 is a batch process reactor including a vacuum system for providing a leak tight environment. Reactor 310 is capable of eliminating trace amount of oxygen or moisture during anneal.

In one embodiment, reactor 320 is a batch process reactor configured to perform oxidation at atmospheric pressure. Transport chamber 330 provides a controlled environment for wafer transport. In an exemplary embodiment, transport chamber 330 is coupled to reactors 310 and 320 through a load lock transport system. The transport chamber is configure to also provide a continuous flow of an inert gas, such as N₂ and/or Ar.

Wafer processing apparatus 300 can be used to perform the method discussed above with respect to FIGS. 2A-2C according to one embodiment of the present invention. Merely as an example, a process sequence using apparatus 300 is described below. First, a batch of wafers is disposed in the transport chamber 330. The wafers can include various device structures, such as trench structures. A continuous flow of inert gas, such as N₂ or Ar in the transport chamber is used to expel oxygen from the chamber. The wafers are then transported and loaded into reactor 310, in which the hydrogen anneal process is carried out in a low pressure or vacuum condition. Examples of process conditions include those discussed above with reference to FIG. 2A-2C. After the hydrogen anneal process, reactor 310 is purged to remove residual hydrogen and back-filled with an inert gas such as N₂ or Ar to atmospheric pressure. Then, the wafers are transported back to transport chamber 330 which is maintained in an inert environment. The wafers are then transported and loaded into reactor 320 in which batch oxidation process is carried out. In the process described above, during the time between the hydrogen anneal process and the oxidation process, the wafers are not exposed to oxygen, or ambient moisture, or contamination. Native oxide growth or contamination is thus prevented and the quality of the oxide improved.

In one embodiment, the first reactor 310 further includes a first wafer carrier 312 for supporting two or more wafers for performing hydrogen anneal in batch mode. The second reactor 320 includes a second wafer carrier 322 for supporting two or more wafers for forming the dielectric layer in batch mode. In another embodiment, transport chamber 330 also includes wafer carrier 332 for transferring multiple wafers to and from reactors 310 and 320. These carriers enable batch mode processing, which improves the throughput of a manufacturing process.

In an alternate embodiment of the invention, reactor 320 in FIG. 3A can be a reactor for other dielectric layer growth. For example, reactor 320 can be a reactor for silicon nitridation. In another example, reactor 320 can be a reactor for dry or wet oxidation. In yet another example, reactor 320 can be used for low pressure oxidation, or low pressure CVD of a dielectric layer. Still other variations, modifications, and alternatives can be envisioned by one skilled in this art in view of this disclosure.

FIG. 3B shows a simplified schematic diagram of an apparatus 350 for integrated circuit processing according to another embodiment of the present invention. Integrated circuit processing apparatus 350 is an apparatus for performing hydrogen anneal in reduced pressure and forming a dielectric layer in atmospheric pressure. Process apparatus 350 includes reactor 360 configured for batch processing a plurality of semiconductor wafers. The reactor is capable of maintaining a leak tight condition under a reduced pressure. Certain reduced pressure process conditions are discussed above with reference to FIGS. 2A-2C. The apparatus also includes a vacuum system 370 coupled to the reactor 360 for maintaining the reactor in a reduced pressure. The apparatus includes a wafer carrier 362 in the reactor for supporting the plurality of semiconductor wafers 364 in the reactor during processing. The apparatus includes a heating system (not shown) for maintaining the reactor in a temperature range of about 800° C. to 1200° C. In embodiments of the invention, the apparatus also includes supplies of various process gases. These process gas supplies include, for example, a hydrogen gas supply 382 coupled to the reactor for supplying hydrogen gas for annealing the plurality of semiconductor wafers, an inert gas supply 384 coupled to the reactor for purging the reactor using N₂ or Ar, and an oxygen gas supply 386 coupled to the reactor for forming the dielectric layer.

In a specific embodiment of the invention, the annealing of the trench structure and forming the dielectric layer are performed in a single chamber apparatus, such as 350 in FIG. 3B. The trench structure is first annealed in a hydrogen ambient under reduced pressure. The chamber is then purged to remove the hydrogen gas and filled with an inert gas to about atmospheric pressure. The dielectric layer is then formed in atmospheric pressure.

The processing of a trench structure using the integrated hydrogen anneal and gate oxide formation process according to the present invention can be viewed as an independent process module, which can be performed at different points within the process flow of a variety of different trench FET processes. For example, this trench anneal and oxidation module can be used in the manufacture of a trench MOSFET, as described next, by employing the module prior to formation of the well (or body) and source regions of the trench MOSFET. Alternatively, the trench formation process can be used in forming other trench FET structure such as a shielded gate FET.

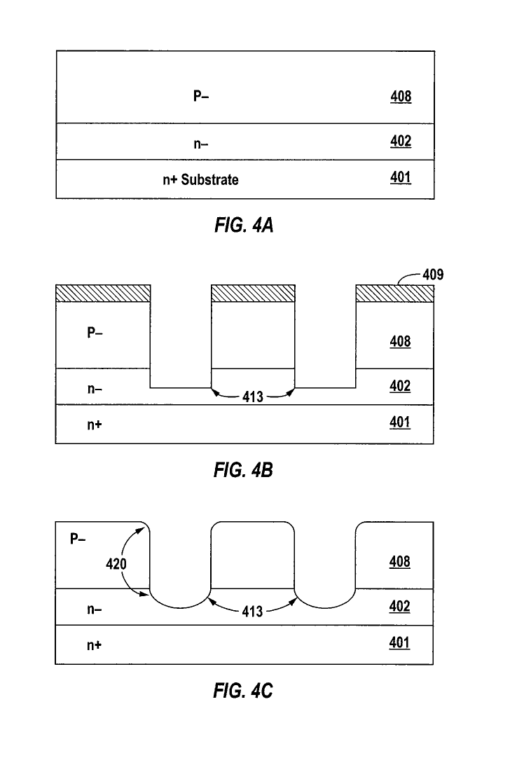

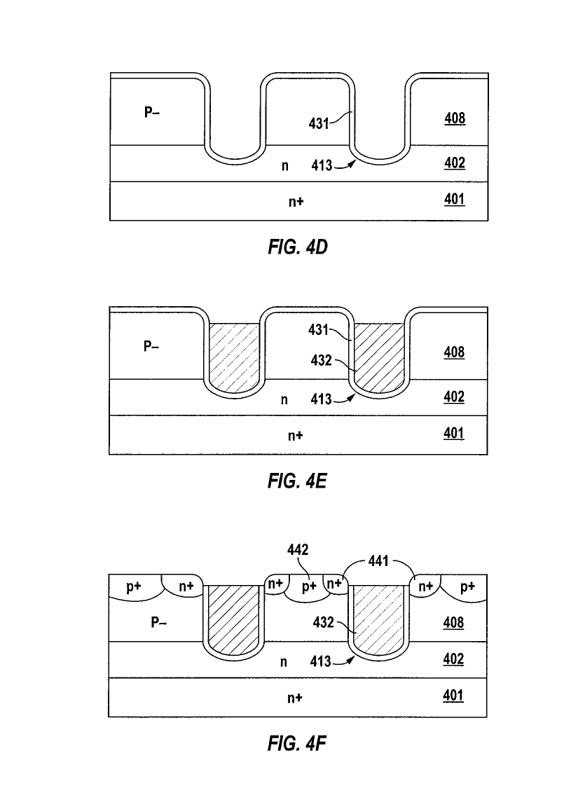

FIGS. 4A-4F are simplified cross-section views illustrating a process flow for manufacturing a trench-gate FET using an integrated hydrogen anneal and gate oxidation process according to an embodiment of the present invention. In FIG. 4A, an n-type epitaxial layer 402 is formed over an n-type substrate 401 using conventional techniques. A p-type body region 408 is formed in epitaxial layer 402 by implanting and diffusing dopants of p-type conductivity into epitaxial layer 402.

In FIG. 4B, masking layer 409 is formed on top of body region 408 by a conventional method. The masking layer is patterned to define openings through which trenches 413 are formed. A conventional anisotropic silicon etch may be used to etch trenches extending through body region 408 and terminating below the bottom surface of body region 408. Cells of alternating trenches 413 and mesas are thus formed. As shown in FIG. 4B, the method includes forming at least one trench into the epitaxial layer, each trench defined by a first end in a plane defined by a major surface of the substrate and by walls that extend to a second end at a predetermined depth into the epitaxial layer.

In FIGS. 4C and 4D, masking layer 409 is removed and then an integrated hydrogen anneal and gate oxidation process is perform according to an embodiment of the invention. An example of such a process is discussed above with reference to FIGS. 2A-2D. Other examples of hydrogen anneal is described in the commonly-assigned U.S. Pat. No. 6,825,087, entitled “Hydrogen Anneal for Creating an Enhanced Trench for Trench MOSFETs,” incorporated herein by reference in its entirety.

The hydrogen anneal not only reduces the defect density of the base silicon layer but it also causes the upper and lower corners 420 of trenches 413 to become rounded, as shown in FIG. 4C. A gate dielectric formation process is then carried out following the hydrogen anneal without exposing the trenches to oxygen. The gate dielectric may be formed by a conventional gate oxidation process in dry or wet oxygen ambient, at atmospheric or reduced pressure. In certain embodiments, the gate dielectric process may include fluorine or nitrogen to further improve the quality of the gate dielectric. Of course, there can be other variations, modifications, and alternatives. In FIG. 4D, a thin gate dielectric 431 (e.g., comprising oxide) lines the sidewalls and bottom of trenches 413. With the integrated hydrogen anneal and gate dielectric formation process, gate dielectric 431 is of higher quality than in conventional FETs.

In FIG. 4E, recessed gate electrode 432 (e.g., comprising polysilicon) is formed in trench 413 using conventional techniques. In FIG. 4F, highly doped n-type source regions 441 are formed in body regions 408 adjacent trenches 413 using conventional source implant techniques. Heavy body regions 442 are also formed using, for example, convention ion implantation techniques. The active regions of the field effect transistor are thus formed between source regions 441 and substrate (or drain contact) 401 along the sides of each trench 413. In subsequent processes, not shown, backend processes are carried out to form the remaining layers and structures such as the interconnect layers and passivation.

An example of a trench MOSFET process describing various steps before and after the trench formation process module can be found in U.S. patent application Ser. No. 11/140,567, entitled “Structure and Method for Forming a Minimum Pitch Trench-Gate FET with Heavy Body Region,” which is hereby incorporated by reference.

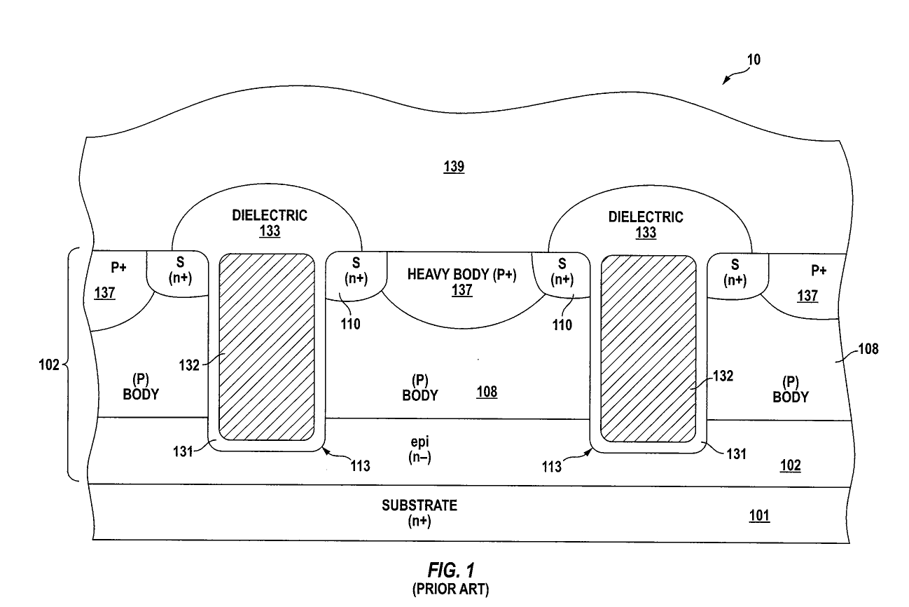

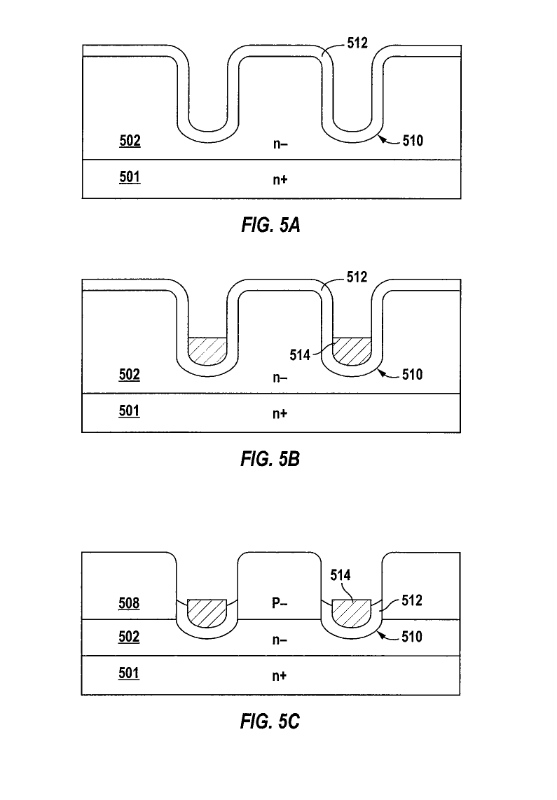

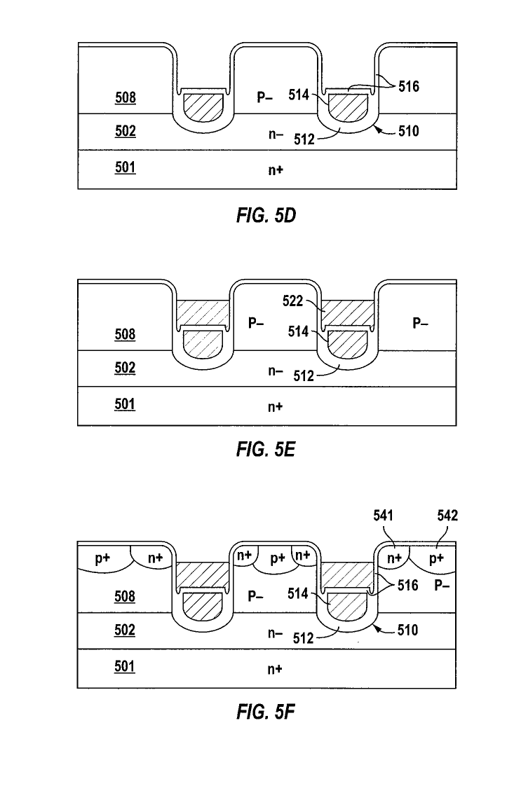

FIG. 5A-5F are simplified cross section views at various steps of a process for forming a shielded gate trench FET using an integrated hydrogen anneal and gate oxidation process according to an embodiment of the present invention. In FIG. 1A, an n-type epitaxial layer 402 is formed over substrate 502 using known techniques. Trenches 510 are formed in an n-type semiconductor region 502. A shield dielectric 512 (e.g., comprising oxide) is formed lining the trench sidewalls and bottom surface and extending over mesa regions adjacent the trenches. In one embodiment, an integrated hydrogen anneal and oxidation process may be use to treat the silicon surface and to form the shield dielectric, as described in reference to the previous embodiment.

In FIG. 5B, shield electrode 514 is formed in a bottom portion of trenches 510 using known techniques. For example, a conductive material (e.g., comprising doped or undoped polysilicon) is first formed filling the trenches and extending over the mesa regions. The conductive material is recessed deep into trenches 510 to form shield electrode 514 using known techniques.

In FIG. 5C, using known methods, shield dielectric 512 is removed from along the exposed upper trench sidewalls and over mesa surfaces. Body region 508 is formed in epitaxial layer 502 using conventional implant and drive in techniques. Note that body region 508 may be formed in an earlier or later stage of the process. In FIG. 5D, an integrated hydrogen anneal and gate oxidation are perform using the processes described above with reference to FIGS. 2A-2C to form gate dielectric layer 516 extending along the upper trench sidewalls. This process also results in oxidation of shield electrodes 514 thus forming an inter-electrode dielectric (IED) layer over shield electrodes 514. In an alternate embodiment wherein a thicker IED is desired, prior to performing the integrated hydrogen anneal and gate oxidation, a thick dielectric layer is formed over shield electrode 514.

In FIG. 5E, recessed gate electrodes 522 are formed in trenches 510 using known techniques. In FIG. 5F, highly doped n-type source regions 541 are formed in body regions 508 adjacent trenches 510 using conventional source implant techniques. Heavy body regions 542 are also formed using, for example, convention ion implantation techniques. In subsequent processes, not shown, the remaining layers and structures such as interconnect and passivation are formed.

According to embodiments of the present invention, the shield electrode in a shielded gate FETs can be floating (i.e., is electrically unbiased), biased to the source potential (e.g., ground potential), or biased to the same potential as the gate electrode. The electrical contact between the gate and shield electrodes may be formed in any non-active region, such as in the termination or edge regions of the die.

Incorporation of the integrated hydrogen anneal and gate dielectric formation process module of the present invention into the manufacturing process of a trench FET can produce a higher performance trench MOSFET, which displays a more uniform electric field distribution around the gate area and reduced gate leakage currents. The reliability of the trench FET is also improved.

While the above is a complete description of specific embodiments of the present invention, various modifications, variations, and alternatives may be employed. For example, although silicon is given as an example of a substrate material, other materials may be used. The invention is illustrated using trench MOSFETs, but it could easily be applied to other trench-gate structures such as IGBTs by merely reversing the polarity of the substrate. Similarly, implantation is given as an example of introducing dopants, but other doping methods, such as a gas or topical dopant source may be used to provide dopants for diffusion, depending on the appropriate mask being used. The process sequences depicted are for n-channel FETs, but modifying these process sequences to form p-channel FETs would be obvious to one skilled in the art in view of this disclosure. Also, while some trenches discussed above are shown to terminate within the epitaxial layer, the trenches may alternatively extend through the epitaxial layer and terminate within the substrate region. Further, the manufacturing process depicted by FIGS. 4A-4F can be modified by one skilled in the art to include a thick bottom oxide (TBO) under the gate electrodes to reduce the gate-drain charge. Hence, the scope of this invention should not be limited to the embodiments described, but are instead defined by the following claims.

1. A method for forming a trench gate field effect transistor, comprising:
forming trenches in a semiconductor substrate;
annealing the semiconductor substrate in an ambient including hydrogen gas;
forming a dielectric layer lining at least the sidewalls of the trenches; and
during the time between the annealing and forming the dielectric layer, maintaining the semiconductor substrate in an inert environment to prevent formation of native oxide along sidewalls of the trenches prior to forming the dielectric layer.

2. The method of claim 1 wherein the forming a dielectric layer comprises performing an oxidation process to form a gate oxide layer along the sidewalls of the trenches.

3. The method of claim 1 wherein the forming of a dielectric layer comprises performing a nitridation process to form a silicon nitride layer along the sidewalls of the trenches.

4. The method of claim 1 further comprising:
forming an epitaxial layer of a first conductivity type over a drain contact region of the first conductivity type, the epitaxial layer having a higher resistivity than the drain contact region, wherein the trenches extend into and terminate within the epitaxial layer.

5. The method of claim 4 further comprising:
after forming the dielectric layer, forming a gate electrode in each trench;
forming a well region of a second conductivity type in the epitaxial layer;
forming source regions of the first conductivity type in the well region; and
forming heavy body regions of the second conductivity type in the well region.

6. The method of claim 5 further comprising:
prior to forming a gate electrode in each trench, filling a bottom portion of each trench with a thick bottom dielectric, the thick bottom dielectric being thicker than the dielectric layer.

7. The method of claim 1 wherein the annealing of the semiconductor substrate is performed at a temperature within the range of about 700° C. to 1200° C. and at a pressure within a range of about 100 mTorr to 450 Torr.

8. The method of claim 1 wherein the annealing of the semiconductor substrate is performed at a temperature within the range of about 960° C. to 1160° C. and at a pressure within a range of about 40 Torr to 240 Torr.

9. The method of claim 1 wherein the annealing of the semiconductor substrate is performed at a temperature within the range of about 800° C. to 1000° C. and a pressure within the range of about 200 mTorr to 400 mTorr.

10. The method of claim 1 further comprising:
annealing the semiconductor substrate in a first reactor in a hydrogen ambient under reduced pressure;
purging the first reactor to remove the hydrogen gas;
transferring the semiconductor substrate from the first reactor to a second reactor through a transport chamber having an inert ambient; and
forming the dielectric layer in the second reactor in atmospheric pressure.

11. The method of claim 1 further comprising:
annealing the semiconductor substrate in a chamber having a hydrogen ambient under reduced pressure;
purging the chamber to remove the hydrogen gas;
filling the chamber with an inert gas; and
forming the dielectric layer in the chamber under atmospheric pressure.

12. A method for forming a trench gate field effect transistor, comprising:
forming trenches in a semiconductor substrate of a first conductivity type;
annealing the semiconductor substrate in an ambient including hydrogen gas;
performing an oxidation process to form a layer of gate oxide along the sidewalls of the trenches;
during the time between the annealing and performing an oxidation process, maintaining the semiconductor substrate in an inert environment to prevent formation of native oxide along sidewalls of the trenches prior to forming the layer of gate oxide;
forming a gate electrode in each trench;
forming a well region of a second conductivity type in the semiconductor substrate;
forming source regions of the first conductivity type in the well region; and
forming heavy body regions of the second conductivity type in the well region.

13. The method of claim 12 wherein the semiconductor substrate comprises an epitaxial layer over a drain contact region, the epitaxial layer having a higher resistivity than the drain contact region, wherein the well region is formed in the epitaxial layer, and the trenches extend through the well region and terminate within the epitaxial layer.

14. The method of claim 12 wherein the annealing of the semiconductor substrate is performed at a temperature within the range of about 700° C. to 1200° C. and at a pressure within a range of about 100 mTorr to 450 Torr.

15. A method of forming a shielded gate field effect transistor, comprising:
forming trenches in a semiconductor substrate;
forming a shield dielectric layer lining lower sidewalls and bottom of each trench;
forming a shield electrode filling a bottom portion of each trench;
annealing the semiconductor substrate in an ambient including hydrogen gas;
forming a dielectric layer lining at least the upper sidewalls of each trench;
during the time between the annealing and forming the dielectric layer, maintaining the semiconductor substrate in an inert environment to prevent formation of native oxide along upper sidewalls of each trench prior to forming the dielectric layer; and
forming a gate electrode in an upper portion of each trench.

16. The method of claim 15 wherein the forming a dielectric layer comprises performing an oxidation process to form a gate oxide layer along upper sidewalls of each trench.

17. The method of claim 16 wherein the oxidation process results in formation of a dielectric layer over the shield electrode in each trench.

18. The method of claim 15 wherein the forming of a dielectric layer comprises performing a nitridation process to form a silicon nitride layer along upper sidewalls of each trench.

19. The method of claim 15 further comprising:
prior to forming the dielectric layer, forming an inter-electrode dielectric layer over the shield electrode, the inter-electrode dielectric layer serving to insulate the shield electrode and the gate electrode from one another.

20. The method of claim 15 further comprising:
forming an epitaxial layer of a first conductivity type over a drain contact region of the first conductivity type, the epitaxial layer having a higher resistivity than the drain contact region, wherein the trenches extend into and terminate within the epitaxial layer.

21. The method of claim 15 further comprising:
forming a well region of a second conductivity type in the semiconductor substrate;
forming source regions of the first conductivity type in the well region; and
forming heavy body regions of the second conductivity type in the well region.

22. The method of claim 15 wherein the annealing of the semiconductor substrate is performed at a temperature within the range of about 700° C. to 1200° C. and at a pressure within a range of about 100 mTorr to 450 Torr.

23. The method of claim 15 wherein the annealing of the semiconductor substrate is performed at a temperature within the range of about 960° C. to 1160° C. and at a pressure within a range of about 40 Torr to 240 Torr.

24. The method of claim 15 wherein the annealing of the semiconductor substrate is performed at a temperature within the range of about 800° C. to 1000° C. and a pressure within the range of about 200 mTorr to 400 mTorr.

25. The method of claim 15 further comprising:
after forming the shield electrode:
annealing the semiconductor substrate in a first reactor in a hydrogen ambient under reduced pressure;
purging the first reactor to remove the hydrogen gas;
transferring the semiconductor substrate from the first reactor to a second reactor through a transport chamber having an inert ambient; and
forming the dielectric layer in the second reactor under atmospheric pressure.

26. The method of claim 15 further comprising:
after forming the shield electrode:
annealing the semiconductor substrate in a chamber having a hydrogen ambient under reduced pressure;
purging the chamber to remove the hydrogen gas;
filling the chamber with an inert gas; and
forming the dielectric layer in the chamber under atmospheric pressure.

27. A method of forming a shielded gate field effect transistor, comprising:
forming trenches in a semiconductor substrate of a first conductivity type;
forming a shield dielectric layer lining lower sidewalls and bottom of each trench;
forming a shield electrode filling a bottom portion of each trench;
annealing the semiconductor substrate in an ambient including hydrogen gas;
performing an oxidation process to form a layer of gate oxide along upper sidewalls of each trench;
during the time between the annealing and performing an oxidation process, maintaining the semiconductor substrate in an inert environment to prevent formation of native oxide along upper sidewalls of each trench prior to forming the layer of gate oxide;
forming a gate electrode in an upper portion of each trench;
forming a well region of a second conductivity type in the semiconductor substrate;
forming source regions of the first conductivity type in the well region; and
forming heavy body regions of the second conductivity type in the well region.

28. The method of claim 27 wherein the oxidation process results in formation of a dielectric layer over the shield electrode in each trench.

29. The method of claim 27 further comprising:
prior to forming the dielectric layer, forming an inter-electrode dielectric layer over the shield electrode, the inter-electrode dielectric layer serving to insulate the shield electrode and the gate electrode from one another.

30. The method of claim 27 wherein the semiconductor substrate comprises an epitaxial layer over a drain contact region, the epitaxial layer having a higher resistivity than the drain contact region, wherein the well region is formed in the epitaxial layer, and the trenches extend through the well region and terminate within the epitaxial layer.

31. The method of claim 27 wherein the annealing of the semiconductor substrate is performed at a temperature within the range of about 700° C. to 1200° C. and at a pressure within a range of about 100 mTorr to 450 Torr.

32-40. (canceled)
